(19) United States
(12) Patent Application Publication
(10) Pub. No.: US 2007/0145992 A1
(43) Pub. Date: Jun. 28, 2007

(54) Semiconductor device testing system and semiconductor device testing method

(75) Inventors: Kouji Akahori, Kyoto (JP); Tsuneaki Ishimaru, Yamaguchi (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/644,956

(22) Filed: Dec. 26, 2006

(30) Foreign Application Priority Data
Dec. 27, 2005 (JP) 2005-373662

(51) Int. Cl. G01R 31/02

(52) U.S. Cl. 324/755

(57) ABSTRACT

When a convex jig pushes up a bottom face of an adhesive sheet where a target semiconductor device is located, a non-target semiconductor device located near the target semiconductor device is lower in position than the target semiconductor device. Thus, the non-target semiconductor device is prevented from coming into contact with an impedance adjusting element and a coaxial connector each provided for high-frequency measurement near a socket.

### BACKGROUND OF THE INVENTION

(1) Field of the Invention

The present invention relates to a test for a semiconductor device. More particularly, the present invention relates to a semiconductor device testing system and a semiconductor device testing method each used for carrying out an electrical characteristic test on a high-frequency semiconductor device.

(2) Description of the Related Art

Recently, there is required a semiconductor device having good high-frequency characteristics and being usable to high-frequency equipment such as a mobile telephone. In a testing system for such a semiconductor device, a testing board serving as a relay is provided between the testing system and a target semiconductor device. Herein, signal lines in the testing board are configured by microstrip lines in consideration of high-frequency characteristics. Further, an impedance adjusting element and a coaxial connector are provided on the testing board in order to adjust the high-frequency characteristics.

In the semiconductor device testing system, a socket to be connected to a testing electrode of a semiconductor device is provided on the testing board. The socket requires a short contactor in order to secure high-frequency characteristics. Typically, a pogo pin or an anisotropic conductive sheet is used as the socket.

On the other hand, the semiconductor device is mounted on a semiconductor wafer while being packaged. As a semiconductor package, in order to achieve size reduction, there is used a wafer level chip size package (WLCSP) that a solder ball is attached to an electrode of a semiconductor device formed on a semiconductor wafer so as to connect between the semiconductor device and the semiconductor wafer.

Hereinafter, description will be given of a conventional semiconductor device testing system for carrying out an electrical characteristic test on the aforementioned WLCSP semiconductor device with reference to the drawings (refer to, for example, JP2004-152916A).

In a WLCSP semiconductor device testing process, normally, a horizontal transfer-type handling apparatus is used for transferring a semiconductor device. In the horizontal transfer-type handling apparatus, as illustrated in FIG. 7, a WLCSP semiconductor device 101 obtained by dicing is transferred from a tray to a measurement section in a semiconductor device testing system and, then, is attached to a socket 105.

Thereafter, a pushing jig 107 moving upward/downward in the horizontal transfer-type handling apparatus applies a load (20 to 30 g per pin) onto a top face (having no electrode) of the semiconductor device 101, so that a contactor of the socket 105 is electrically connected to a testing electrode (a solder ball) of the semiconductor device 101. Thus, an electrical characteristic test is carried out on the semiconductor device 101.

In the aforementioned conventional semiconductor device testing system, however, when the horizontal transfer-type handling apparatus transfers a WLCSP semiconductor device, the following drawbacks are caused. That is, since a size of the WLCSP semiconductor device is very small (not more than 5 mm square), the WLCSP semiconductor device is dropped upon transfer or is erroneously absorbed at the tray or the measurement section. Further, since a distance of a transfer path becomes long, a time for exchanging a semiconductor device is extended.

In the measurement section of the horizontal transfer-type handling apparatus, as illustrated in FIG. 7, alignment of the contactor of the socket 105 with the testing electrode of the WLCSP semiconductor device 101 is performed by a positioning jig 106 of the socket 105 based on an outer dimension of the semiconductor device 101. However, in some cases, the testing electrode of the WLCSP semiconductor device 101 cannot be electrically connected to the contactor of the socket 105 due to an outer dimensional deviation of the WLCSP semiconductor device 101 or erroneous fitting in the positioning jig 106.

In order to prevent a semiconductor device from being dropped or erroneously absorbed upon transfer by the horizontal transfer-type handling apparatus, recently, there is used a frame probing apparatus capable of performing alignment with high accuracy by means of an image recognizing apparatus upon contact of a testing electrode of a semiconductor device with a contactor of a socket.

Unlike the aforementioned handling apparatus transferring a diced semiconductor device, the frame probing apparatus uses a wafer holding tool. More specifically, as illustrated in FIG. 3, a circular adhesive sheet 201 is fixed to an annular frame 202, and a semiconductor wafer 203 is joined onto the adhesive sheet 201. Herein, the adhesive sheet 201 is larger in size than an inner circumferential edge of the frame 202. The semiconductor wafer 203 in the wafer holding tool is diced into semiconductor devices by means of a dicing apparatus.

In order to carry out an electrical characteristic test on a target WLCSP semiconductor device 101, as illustrated in FIG. 8, the wafer holding tool including the adhesive sheet 201 is placed on a stage 204 of the frame probing apparatus, and a socket 105 to be electrically connected to a testing electrode 102 of the target semiconductor device 101 is provided above the stage 204 of the frame probing apparatus in a horizontal direction.

A testing flow by the frame probing apparatus is as follows. First, an image recognizing apparatus (not illustrated) recognizes a position of the testing electrode 102 of the semiconductor device 101, and the stage 204 moves in a horizontal direction and in a vertical direction such that the testing electrode 102 of the semiconductor device 101 comes into contact with a contactor of the socket 105. Thus, the testing electrode 102 of the semiconductor device 101 is aligned with the contactor of the socket 105. Thereafter, when the stage 204 moves upward in the vertical direction, the testing electrode 102 of the target semiconductor device 101 is connected to the contactor of the socket 105 in a measurement section. Thus, an electrical characteristic test is carried out on the semiconductor device 101.

As described above, the frame probing apparatus is superior to the horizontal transfer-type handling apparatus in the following points. That is, alignment of a testing electrode of a target semiconductor device with a contactor of a socket in a measurement section can be performed with high accuracy. In addition, since a distance of a transfer path becomes short, a time for exchanging a semiconductor device can be reduced.

However, since a recent semiconductor device has a high frequency (not less than 1 GHz), an impedance adjusting element 103 (about 1 mm in height) must be provided immediately near the socket 105 on a testing board 104 in the measurement section, as illustrated in FIG. 8. Therefore, the conventional electrical connection by the frame probing apparatus has the following problem. That is, when the stage 204 provided with the wafer holding tool moves upward in the vertical direction, the impedance adjusting element 103 provided for high-frequency measurement disadvantageously comes into contact with an electrode and an electric circuit formed on a top face of a non-target semiconductor device 108 situated near the target semiconductor device 101, so that the electrode and the electric circuit of the non-target semiconductor device 108 are damaged.

### SUMMARY OF THE INVENTION

The present invention is made to solve the aforementioned conventional problems. It is therefore an object of the present invention to provide a semiconductor device testing system and a semiconductor device testing method each capable of achieving the following advantages. That is, even when a measurement section is configured so as to carry out an electrical characteristic test at a high frequency on a high-frequency semiconductor device, an electrode and an electric circuit of a non-target semiconductor device are prevented from being damaged. Further, alignment of a testing electrode of a target semiconductor device with a contactor of a socket can be performed with high accuracy, and a time for exchanging a semiconductor device can be reduced.

In order to accomplish this object, the present invention provides a semiconductor device testing system for electrically connecting between testing electrodes of a semiconductor device and a testing board in a measurement section, thereby to measure electrical parameters of the semiconductor device when carrying out an electrical characteristic test on the semiconductor device, the system comprising a frame having a hole inside thereof; an adhesive sheet fixed to an inner circumferential edge of the hole and having a size larger than the hole, the adhesive sheet having an adhesion face formed on at least one side thereof; a plurality of semiconductor devices joined onto the adhesion face of the adhesive sheet such that a bottom face having no testing electrode of each semiconductor device is directed to the adhesion face; a stage moving in a horizontal direction and a vertical direction, and being mounted thereon with the frame such that a top face of the semiconductor device having testing electrodes is directed upward; a plurality of contactors provided on the testing board are located above the frame, and coming into contact with the testing electrodes of each semiconductor device to supply electric signals from the measurement section to each semiconductor device; and a convex jig provided between the frame and the stage and moving in the horizontal direction and the vertical direction, wherein the convex jig is moved upward in the vertical direction to push up a target semiconductor device of the plurality of semiconductor devices, thereby to bring the testing electrodes of the target semiconductor device into contact with the plurality of contactors on the testing board.

The present invention also provides a semiconductor device testing method for measuring electrical parameters of a semiconductor device when carrying out an electrical characteristic test on the semiconductor device through use of the aforementioned semiconductor device testing system, the semiconductor device testing method comprising: moving the convex jig in the horizontal direction to align the target semiconductor device with a protruding part of the convex jig on the stage; moving the convex jig upward in the vertical direction to push up the target semiconductor device to be higher in position than non-target semiconductor devices each situated near the target semiconductor device; moving the stage in the horizontal direction to align the testing electrodes of the target semiconductor device with the plurality of contactors on the testing board in the measurement section; moving the stage upward in the vertical direction to bring the testing electrodes of the target semiconductor device into contact with the plurality of contactors on the testing board; and electrically connecting between the testing electrodes of the target semiconductor device and the testing board in the measurement section.

According to the present invention, even when the measurement section is configured so as to carry out an electrical characteristic test at a high frequency on a high-frequency semiconductor device, a frame probing apparatus capable of performing alignment with high accuracy is utilized to push up a target semiconductor device from below, so that a non-target semiconductor device situated near the target semiconductor device is lower in position than the target semiconductor device. Therefore, an impedance adjusting element and a coaxial connector each provided for high-frequency measurement near a socket are prevented from coming into contact with the non-target semiconductor device.

Therefore, even when a measurement section is configured so as to carry out an electrical characteristic test at a high frequency on a high-frequency semiconductor device, an electrode and an electric circuit of a non-target semiconductor device are prevented from being damaged. Further, alignment of a testing electrode of a target semiconductor device with a contactor of a socket can be performed with high accuracy, and a time for exchanging a semiconductor device can be reduced.

### BRIEF DESCRIPTION OF THE DRAWINGS

FIG. 1 is a sectional view illustrating a configuration of a convex jig in a semiconductor device testing system according to an embodiment of the present invention;

FIG. 2 is a sectional view illustrating another configuration (movable type) of the convex jig in the semiconductor device testing system according to the embodiment;

FIG. 3 is a perspective view illustrating a configuration of a wafer holding tool in the semiconductor device testing system according to the embodiment;

FIG. 4 is a sectional view illustrating a general configuration of the semiconductor device testing system according to the embodiment;

FIG. 5 is a perspective view illustrating the general configuration of the semiconductor device testing system according to the embodiment;

FIG. 6 illustrates a method for calculating an expanded amount in the semiconductor device testing system according to the embodiment;

FIG. 7 is a sectional view illustrating a configuration of a measurement section of a horizontal transfer-type handling apparatus in a conventional semiconductor device testing system; and

FIG. 8 is a sectional view illustrating a configuration of a measurement section of a frame probing apparatus in a conventional semiconductor device testing system.

### DESCRIPTION OF THE PREFERRED EMBODIMENT

Hereinafter, detailed description will be given of a semiconductor device testing system and a semiconductor device testing method according to an embodiment of the present invention with reference to the drawings.

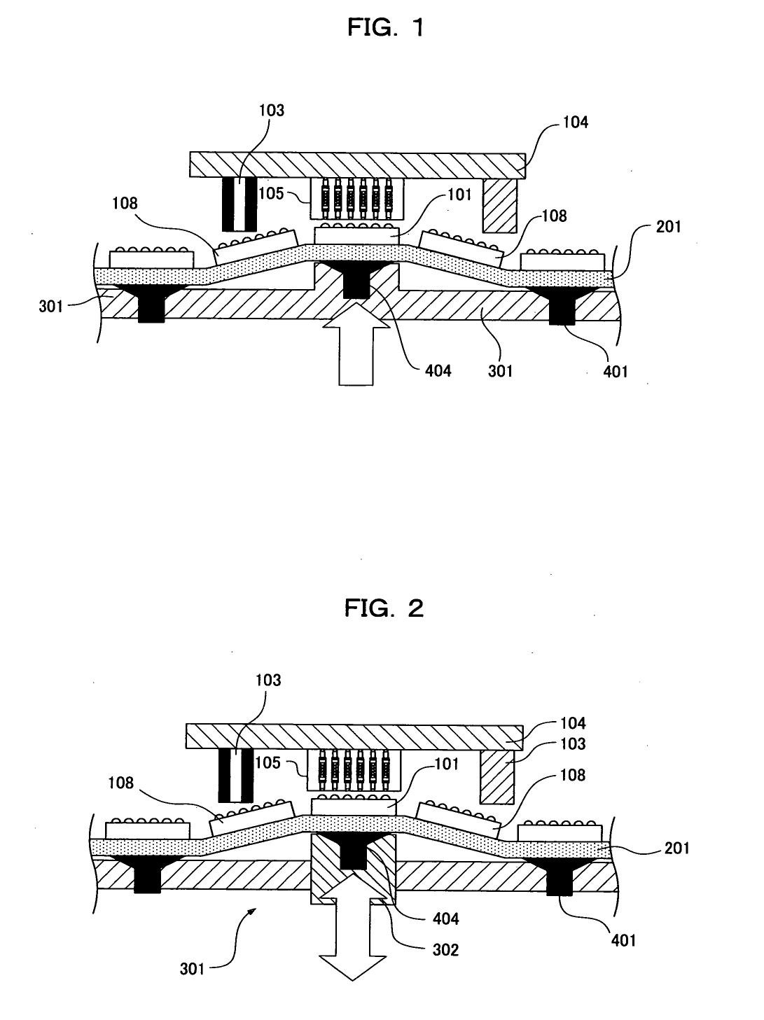

First, description will be given of a configuration of the semiconductor device testing system according the embodiment with reference to FIGS. 1 to 6.

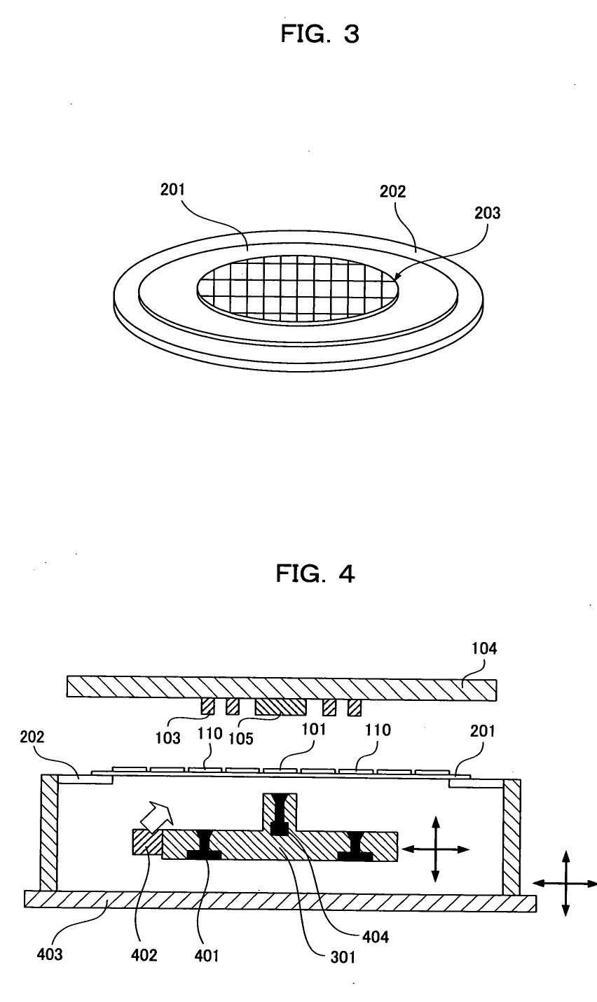

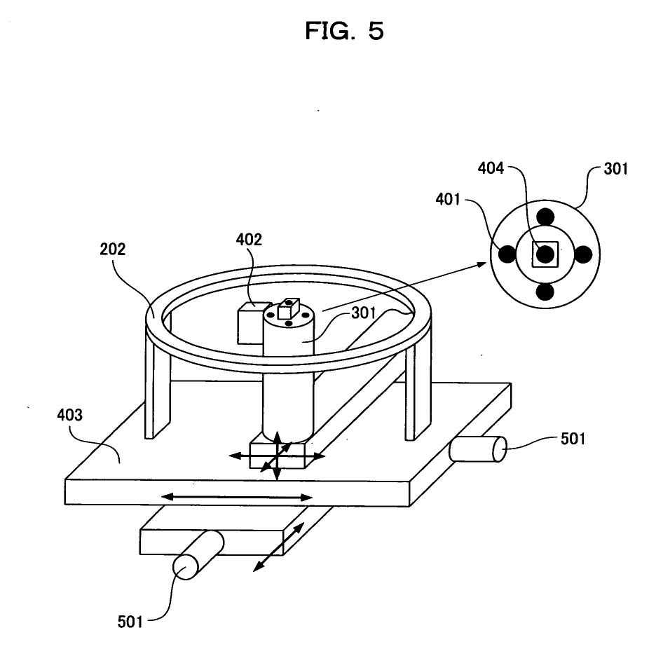

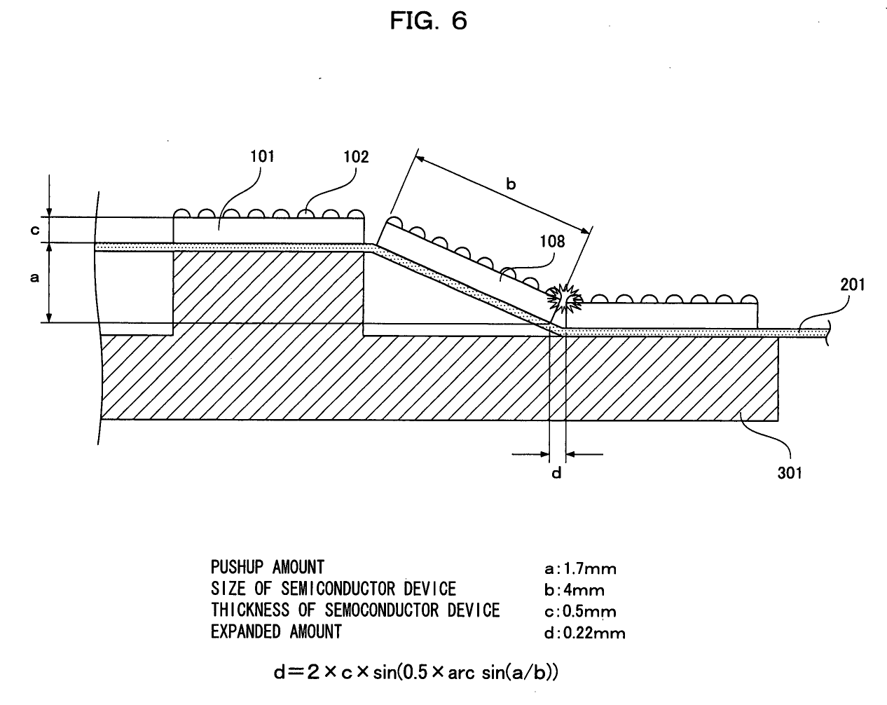

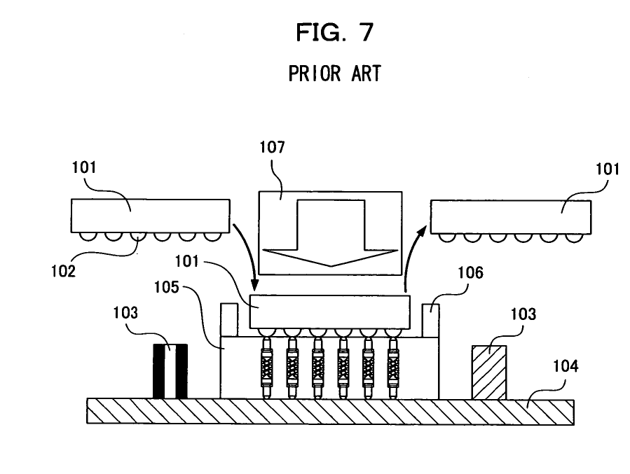

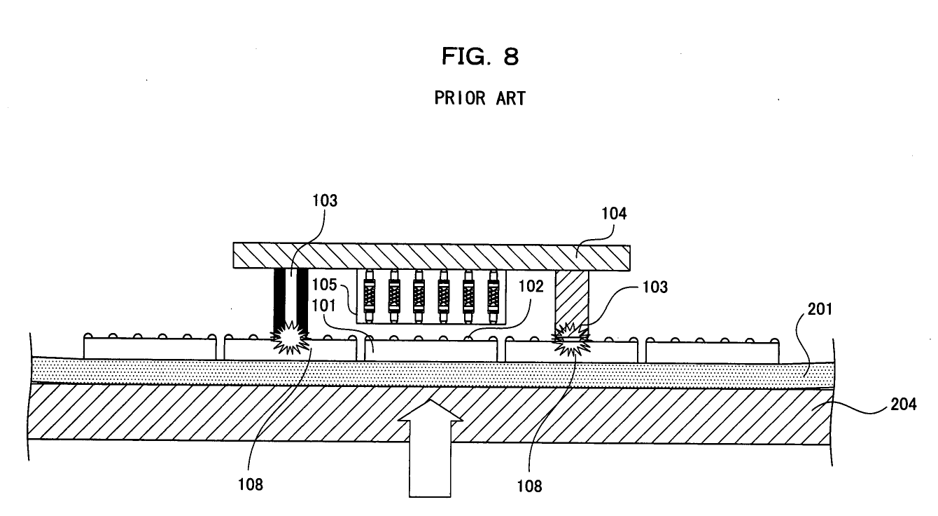

FIG. 1 is a sectional view illustrating a configuration of a convex jig in the semiconductor device testing system according to the embodiment. FIG. 2 is a sectional view illustrating another configuration (movable type) of the convex jig in the semiconductor device testing system according to the embodiment. FIG. 3 is a perspective view illustrating a configuration of a wafer holding tool in the semiconductor device testing system according to the embodiment. FIG. 4 is a sectional view illustrating a general configuration of the semiconductor device testing system according to the embodiment. FIG. 5 is a perspective view illustrating the general configuration of the semiconductor device testing system according to the embodiment. FIG. 6 illustrates a method for calculating an expanded amount in the semiconductor device testing system according to the embodiment.

As illustrated in FIG. 3, a circular adhesive sheet 201 is fixed to an annular frame 202, and a semiconductor wafer 203 is joined onto the adhesive sheet 201 such that a bottom face (having no testing electrode) of a semiconductor device formed on the semiconductor wafer 203 is directed to an adhesion face of the adhesive sheet 201. Herein, the adhesive sheet 201 is larger in size than an inner circumferential edge of the frame 202, and the frame 202 is larger in size than the semiconductor wafer 203. The adhesive sheet 201 used herein has the following natures. That is, when the adhesion face of the adhesive sheet 201 is irradiated with ultraviolet rays, adhesiveness thereof becomes weak. Further, the adhesive sheet 201 is shrunk by addition of heat.

The semiconductor wafer 203 joined onto the adhesive sheet 201 is diced into semiconductor devices by means of a dicing apparatus. When a protruding part of a convex jig 301 pushes up a target semiconductor device 101 as illustrated in FIG. 1, the adhesive sheet 201 is expanded to form a predetermined clearance between adjoining semiconductor devices in order to prevent the following disadvantage: adjoining non-target semiconductor devices 108 each situated near the target semiconductor device 101 are damaged by mutual contact as illustrated in FIG. 6.

Hereinafter, description will be given of an equation for calculating an expanded amount of the adhesive sheet 201 required for forming the predetermined clearance between adjoining semiconductor devices.

A distance from a tip end of the protruding part of the convex jig 301 to a stage is set at about 2 mm twice as long as a height (about 1 mm) of an impedance adjusting element provided for high-frequency measurement on a testing board, in order to prevent disadvantageous contact. An anisotropic conductive sheet is used as a socket. As for the anisotropic conductive sheet, a thickness is set at 0.5 mm and a compressing distance upon contact with an electrode of a semiconductor device is set at 0.3 mm. A required pushup amount “a” by the protruding part of the convex jig 301 is actually 1.7 mm.

When a thickness “c” of a semiconductor device is set at 0.5 mm and a size “b” thereof is set at 4 mm square, an expanded amount “d” of the adhesive sheet 201 required for securing a distance that adjoining semiconductor devices each situated near a target semiconductor device are prevented from coming into contact with each other is calculated from the following equation. Desirably, the expanded amount “d” is not less than 0.22 mm.
d=2×c×sin(0.5×arc sin(a/b))
a: pushup amount
b: size of semiconductor device
c: thickness of semiconductor device
d: expanded amount

Based on the expanded amount “d” (not less than 0.22 mm) calculated from this equation, the adhesive sheet 201 is expanded for forming a predetermined clearance between adjoining semiconductor devices obtained by dicing the semiconductor wafer 203 by means of a dicing apparatus.

As described above, the adhesive sheet 201 is expanded to form a predetermined clearance between adjoining semiconductor devices obtained by dicing the semiconductor wafer 203, and the wafer holding tool holds each semiconductor device as illustrated in FIG. 4. The wafer holding tool is placed on a stage 403 movable in a horizontal direction and in a vertical direction such that a top face (having an electrode) of each semiconductor device is directed upward. Herein, positional accuracy of the stage 403 is a most important factor for contact of a testing electrode of a semiconductor device with a contactor of a socket 105. Therefore, both a vertical deviation and a horizontal deviation about the positional accuracy must fall within ±10 μm.

A testing board 104 movable in the horizontal direction and in the vertical direction is located above the wafer holding tool such that the contactor of the socket 105 provided on the testing board 104 is directed downward. As the socket 105, a pogo pin or an anisotropic conductive sheet having a short contactor (not more than about 1 mm) is used for achieving good high-frequency characteristics.

As illustrated in FIG. 4, the convex jig 301 is provided between the wafer holding tool and the stage 403 so as to be movable in the horizontal direction and in the vertical direction. Positional accuracy of the convex jig 301 may be rough because it is used for performing temporal alignment of the contactor of the socket 105 with the electrode of the semiconductor device 101. Therefore, it is sufficient that both a vertical deviation and a horizontal deviation about the positional accuracy fall within ±100 μm.

A tip end of the protruding part of the convex jig 301 is formed into a flat plane coming into contact with the adhesive sheet 201 and, also, has a size smaller than a semiconductor device. The protruding part of the convex jig 301 may be changed to a protruding part 302 movable in the vertical direction as illustrated in FIG. 2. A movable range of the protruding part 302 is about 2 mm from the top face of the stage 403. When the protruding part 302 of the convex jig 301 is formed so as to be movable, a pushup amount of the target semiconductor device 101 can be adjusted.

When the convex jig 301 pushes up the target semiconductor device 101, the non-target semiconductor device 108 situated near the target semiconductor device 101 floats, thereby to come into contact with the impedance adjusting element 103. In order to prevent this floating, four absorbing apparatuses 401 each attached to the convex jig 301 at a position lower than the protruding part absorb a bottom face of the adhesive sheet 201 where the non-target semiconductor device 108 is situated, at four points as illustrated in FIGS. 4 and 5. Desirably, each of the absorbing apparatuses 401 includes an absorbing part made of a silicon pad in order to enhance absorbing performance.

Also when the convex jig 301 pushes up the target semiconductor device 101, a position of the target semiconductor device 101 is deviated. In order to prevent the positional deviation, as illustrated in FIGS. 4 and 5, an absorbing apparatus 404 for absorbing the bottom face of the adhesive sheet 201 is attached to the tip end of the protruding part of the convex jig 301. Desirably, the absorbing apparatus 404 includes an absorbing part made of a silicon pad in order to enhance absorbing performance.

Also when the convex jig 301 pushes up the target semiconductor device 101, the adhesive sheet 201 near the target semiconductor device 101 is extended. Thus, in a subsequent semiconductor device pickup process, a pickup position of the target semiconductor device 101 is deviated due to the expansion of the adhesive sheet 201, leading to erroneous pickup of the target semiconductor device 101.

In order to prevent this disadvantage, when hot air is applied to the adhesive sheet 201, the adhesive sheet 201 is restored by means of its thermal shrinkage property. As illustrated in FIGS. 4 and 5, a hot-air blowing apparatus 402 having a function of applying hot air is provided at a side face of the convex jig 301, so that hot air is applied to the bottom face of the adhesive sheet 201 near the target semiconductor device 101.

Hereinafter, description will be given of a general flow of a semiconductor device testing method by means of the aforementioned semiconductor device testing system with reference to FIGS. 4 and 5.

First, the target semiconductor device 101 on the wafer holding tool is aligned with the protruding part of the convex jig 301. After performance of the alignment, the convex jig 301 moves upward toward the semiconductor wafer 203 in the vertical direction, and the absorbing apparatus 404 attached to the tip end of the protruding part of the convex jig 301 absorbs the bottom face of the adhesive sheet 201 where the target semiconductor device 101 is situated. Then, the convex jig 301 further moves upward, and the absorbing apparatuses 401 each provided at the position lower than the protruding part of the convex jig 301 absorb the adhesive sheet 201. More specifically, as illustrated in FIGS. 4 and 5, the four absorbing apparatuses 401 absorb the bottom face of the adhesive sheet 201 where the non-target semiconductor device 110 is situated, at four points.

Then, the convex jig 301 pushes up the target semiconductor device 101 such that the position of the target semiconductor device 101 is higher than that of the non-target semiconductor device 110 situated near the target semiconductor device 101 by about 2 mm. In the state that the convex jig 301 pushes up the target semiconductor device 101, the stage 403 having the wafer holding tool placed thereon and the testing board 104 perform alignment of the testing electrode of the target semiconductor device 101 with the contactor of the socket 105 attached to the testing board 104.

After performance of the alignment, the stage 403 and the convex jig 301 move upward simultaneously, so that the testing electrode of the target semiconductor device 101 is electrically connected to the contactor of the socket 105 in the measurement section without contact of the non-target semiconductor device 110 with the impedance adjusting element 103 provided on the testing board 104. Thus, an electrical characteristic test is carried out on the target semiconductor device 101.

After completion of the electrical characteristic test, the absorbing apparatus 404 provided at the protruding part of the convex jig 301 and the absorbing apparatuses 401 each provided at a position lower than the protruding part of the convex jig 301 are deactivated, respectively, so as to release the absorption of the adhesive sheet 201. Then, the stage 403 and the convex jig 301 simultaneously move downward in the vertical direction such that the distance from the tip end of the contactor of the socket 105 to the top face of the wafer holding tool becomes 2 mm; thus, the wafer holding tool is separated from the socket 105.

The convex jig 301 further moves downward such that the distance from the bottom face of the wafer holding tool to the tip end of the convex jig 301 on the stage 403 becomes 2 mm; thus, the wafer holding tool is separated from the convex jig 301. Thereafter, the stage 403 for the wafer holding tool and the convex jig 301 move toward a subsequent target semiconductor device in the horizontal direction. Concurrently, the hot-air blowing apparatus 402 provided at the side face of the convex jig 301 applies hot air to the adhesive sheet 201 near the measured semiconductor device 101, so that the adhesive sheet 201 expanded when the convex jig 301 pushes up the semiconductor device 101 is restored.

By repetition of the aforementioned testing flow, it is possible to carry out an electrical characteristic test on a plurality of semiconductor devices each attached to the wafer holding tool.

What is claimed is:

1. A semiconductor device testing system for electrically connecting between testing electrodes of a semiconductor device and a testing board in a measurement section, thereby to measure electrical parameters of the semiconductor device when carrying out an electrical characteristic test on the semiconductor device, the system comprising
a frame having a hole inside thereof;
an adhesive sheet fixed to an inner circumferential edge of the hole and having a size larger than the hole, the adhesive sheet having an adhesion face formed on at least one side thereof;
a plurality of semiconductor devices joined onto the adhesion face of the adhesive sheet such that a bottom face having no testing electrode of each semiconductor device is directed to the adhesion face;
a stage moving in a horizontal direction and a vertical direction, and being mounted thereon with the frame such that a top face of the semiconductor device having testing electrodes is directed upward;
a plurality of contactors provided on the testing board above the frame, and coming into contact with the testing electrodes of each semiconductor device to supply electric signals from the measurement section to each semiconductor device; and
a convex jig provided between the frame and the stage and moving in the horizontal direction and the vertical direction,
wherein the convex jig is moved upward in the vertical direction to push up a target semiconductor device of the plurality of semiconductor devices, thereby to bring the testing electrodes of the target semiconductor device into contact with the plurality of contactors on the testing board.

2. The semiconductor device testing system according to claim 1, wherein the plurality of contactors on the testing board move in the horizontal direction and the vertical direction.

3. The semiconductor device testing system according to claim 1, wherein the convex jig has a flat plane coming into contact with the adhesive sheet, and the flat plane is smaller in size than the semiconductor device.

4. The semiconductor device testing system according to claim 1, wherein the convex jig moves in the vertical direction.

5. The semiconductor device testing system according to claim 1, wherein a function of absorbing the adhesive sheet is provided on the flat plane of the convex jig coming into contact with the adhesive sheet when the convex jig pushes up the target semiconductor device.

6. The semiconductor device testing system according to claim 1, wherein a function of absorbing the adhesive sheet is provided on a face other than a protruding part of the convex jig.

7. The semiconductor device testing system according to claim 1, wherein the adhesive sheet is made of a material being shrinkable by addition of heat.

8. The semiconductor device testing system according to claim 7, wherein a function of supplying heat to the adhesive sheet for shrinkage thereof is provided near the convex jig.

9. A semiconductor device testing method for measuring electrical parameters of a semiconductor device when carrying out an electrical characteristic test on the semiconductor device through use of the semiconductor device testing system according to claim 1, the semiconductor device testing method comprising:
moving the convex jig in the horizontal direction to align a target semiconductor device with a protruding part of the convex jig on the stage;
moving the convex jig upward in the vertical direction to push up the target semiconductor device to be higher in position than non-target semiconductor devices each situated near the target semiconductor device;
moving the stage in the horizontal direction to align the testing electrodes of the target semiconductor device with the plurality of contactors on the testing board in the measurement section;
moving the stage upward in the vertical direction to bring the testing electrodes of the target semiconductor device into contact with the plurality of contactors on the testing board; and
electrically connecting between the testing electrodes of the target semiconductor device and the testing board in the measurement section.
